(19) United States
(12) Patent Application Publication
(10) Pub. No.: US 2007/0281388 A1
(43) Pub. Date: Dec. 6, 2007

(54) SELECTIVE METAL SURFACE TREATMENT PROCESS AND APPARATUS FOR CIRCUIT BOARD AND RESIST USED IN THE PROCESS

(75) Inventors: Cheng-Po Yu, Taoyuan County (TW); Cheng-Hung Yu, Taoyuan County (TW); Chi-Min Chang, Nantou County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: UNIMICRON TECHNOLOGY CORP., Taoyuan (TW)

(21) Appl. No.: 11/456,213

(22) Filed: Jul. 10, 2006

(30) Foreign Application Priority Data
Jun. 1, 2006 (TW) 95119341

(51) Int. Cl. H01L 21/00; H01L 21/4763

(52) U.S. Cl. 438/106; 438/618; 438/622; 257/E23.106

(57) ABSTRACT

A selective metal surface treatment process of a circuit board, which has a solder mask and a multiple of selective metal treatment surface areas, wherein the solder mask covers the surface of the circuit board but exposes the selective metal surface treatment areas, is provided. The selective metal surface treatment process includes using a printhead to selectively print a resist on a selective metal surface treatment area, performing a surface treatment of the other selective metal surface treatment areas, and removing the resist. A selective metal surface treatment apparatus used for performing the selective metal surface treatment process of the circuit board is also provided. Through the present invention, unnecessary waste of the materials in the process is reduced and the processing time is shortened.

### CROSS-REFERENCE TO RELATED APPLICATION

This application claims the priority benefit of Taiwan application serial no. 95119341, filed Jun. 1, 2006. All disclosure of the Taiwan application is incorporated herein by reference.

### BACKGROUND OF THE INVENTION

1. Field of the Invention

The present invention relates to a circuit board process and related apparatus and material, and more particularly, to a selective metal surface treatment process, apparatus and material for a circuit board process.

2. Description of Related Art

With big advance in technologies and continuous improvement in the quality of life, together with the integration and sustained growth between the computer and communication industry, the fields of applications of integrated circuit (IC) is increasingly wide. Nowadays, integrated circuits are used in various electronic devices including, for example, notebook PC, cell phone, digital camera, personal digital assistant (PDA), printer and optical disk player. The printed circuit board used in integrated circuit packaging process not only serves as a medium for electrical connection, but also serves as a carrier for carrying a chip or other electronic devices.

FIGS. 1A through 1E are diagrams showing the steps for performing a selective Electroless Nickel Immersion Gold (ENIG) plating process of a conventional printed circuit board. The first step in the selective Electroless Nickel Immersion Gold (ENIG) plating process of the printed circuit board is to provide a printed circuit 100 as shown in FIG. 1A. The printed circuit board 100 has a substrate 110, a solder mask 130, a plurality of contacts 120 and a surface circuit 140. The substrate 110 has multilayer circuits (not shown). The solder mask 130 covers the surface 112 of the substrate 110 but exposes the contacts 120. The contacts 120 include a first contact 122 and a second contact 124. Then, dry film (photoresist material) is laminated on the entire printed circuit board 100 by thermal pressure process to form a photoresist layer 150 as shown in FIG. 1B. After that, the printed circuit board 100 is placed on an exposure machine so that the printed circuit board 100 is exposed and developed. The photoresist layer 150 after photo-exposure and development is shown in FIG. 1C. The development step removes the photoresist layer 150 above the second contact 124 while the photoresist layer 150 still covers the first contact 122.

Next, the Electroless Nickel Immersion Gold (ENIG) plating process is performed. That is, a nickel-gold layer 160 is formed to cover the second contact 124 so that the second contact 124 is protected against oxidation as shown in FIG. 1D. In the meantime, the first contact 122 is unaffected by the Electroless Nickel Immersion Gold (ENIG) plating process because of the photoresist layer 150 above the first contact 122. In other words, no nickel-gold layer 160 is deposited on the first contact 122. Thus, a selective Electroless Nickel Immersion Gold (ENIG) plating process such that a nickel-gold layer 160 selectively covers a particular part of the contact 120 can be achieved. Finally, the photoresist layer 150 is removed to produce a printed circuit board 100 as shown in FIG. 1E. Up to this point, the selective Electroless Nickel Immersion Gold (ENIG) plating treatment process is completed.

However, the conventional selective Electroless Nickel Immersion Gold (ENIG) plating process of the printed circuit board 100 has at least the following drawbacks:

1. The process needs to form a photoresist layer 150 having global coverage and perform an exposure and development process to expose the areas (that is, the second contacts 124) that need a nickel-gold layer. However, the actual area of some of the contacts 120 (that is, the first contact 122) that needs to be covered is only a very small portion of the area of the printed circuit board 100. Therefore, the formation of a photoresist layer 150 having a global coverage wastes a lot of materials.

2. Before performing the nickel-gold processing step, the conventional processes including dry film lamination, photo-exposure and development must be carried out. Hence, not only is a long production time and expensive equipment required, but its impact on the environment is also severe.

### SUMMARY OF THE INVENTION

Accordingly, at least one objective of the present invention is to provide a selective metal surface treatment process of a circuit board capable of reducing processing material waste and shortening processing time.

At least another objective of the present invention is to provide a selective metal surface treatment apparatus for performing a selective metal surface treatment process of a circuit board capable of reducing processing material waste and shortening processing time.

At least yet another objective of the present invention is to provide a resist capable of serving as a light-curing material in a selective metal surface treatment process of a circuit board to reduce unnecessary waste of processing material.

At least one more objective of the present invention is to provide a resist capable of serving as a thermal-curing material in a selective metal surface treatment process of a circuit board to reduce unnecessary waste of processing material.

To achieve these and other advantages and in accordance with the purpose of the invention, as embodied and broadly described herein, the invention provides a selective metal surface treatment process of a circuit board. The circuit board has a solder mask and a multiple of selective metal treatment surface areas, wherein the solder mask covers the surface of the circuit board but exposes the selective metal surface treatment areas. The selective metal surface treatment process includes using a printhead to selectively print a resist on a selective metal surface treatment area, performing a surface treatment of the other selective metal surface treatment areas, and removing the printed resist.

In one embodiment of the present invention, after forming the resist on the selective metal surface treatment areas in the foregoing selective metal surface treatment process of the circuit board, further includes illuminating the resist to cure the resist with light.

In one embodiment of the present invention, after forming the resist on the selective metal surface treatment areas in the foregoing selective metal surface treatment process of the circuit board, further includes heating the resist to cure the resist by heat.

In one embodiment of the present invention, the resist used in the foregoing selective metal surface treatment process of the circuit board is in liquid form when it is spray-printed using a printhead. Moreover, a spray-printable resist having an operating temperature range between −20˜200° C. and jettable fluid viscosity range between 0˜100 cps at jetting temperature can be used.

In one embodiment of the present invention, the surface treatment of the other selective metal surface treatment areas in the foregoing selective metal surface treatment process of the circuit board includes a chemical metal surface treatment selected from a group consisting of a nickel-gold treatment, a silver treatment, a tin treatment, a copper treatment and an organic solderability preservative (OSP) treatment.

In one embodiment of the present invention, the surface treatment of the other selective metal surface treatment areas in the foregoing selective metal surface treatment process of the circuit board includes a physical metal surface treatment selected from a group consisting of evaporation plating, ion implantation, plasma processing and polishing.

The present invention also provides a selective metal surface treatment apparatus for processing a circuit board. The circuit board has a solder mask and a multiple of selective metal treatment surface areas, wherein the solder mask covers the surface of the circuit board but exposes the selective metal surface treatment areas. The selective metal surface treatment apparatus includes a printing platform and a removing apparatus. The printing platform is used for carrying the circuit board. The printing platform includes a printhead for selectively printing a resist on a selective metal surface treatment area. The removing apparatus is used for removing the printed resist after completing the surface treatment of other selective metal surface treatment areas.

In one embodiment of the present invention, the foregoing selective metal surface treatment apparatus for processing the circuit board further includes a light-curing apparatus for irradiating the resist and curing the resist with light.

In one embodiment of the present invention, the foregoing selective metal surface treatment apparatus for processing the circuit board further includes a thermal-curing apparatus for heating the resist and curing the resist by heat.

In one embodiment of the present invention, the resist used in the selective metal surface treatment apparatus for processing the circuit board is in liquid form when it is spray-printed using a printhead. Moreover, a spray-printable resist having an operating temperature range between −20˜200° C. and jettable fluid viscosity range between 0˜100 cps at jetting temperature can be used.

In one embodiment of the present invention, the surface treatment of the other selective metal surface treatment areas using the foregoing selective metal surface treatment apparatus for processing the circuit board includes a chemical metal surface treatment selected from a group consisting of a nickel-gold treatment, a silver treatment, a tin treatment, a copper treatment and an organic solderability preservative (OSP) treatment.

In one embodiment of the present invention, the surface treatment of the other selective metal surface treatment areas using the foregoing selective metal surface treatment apparatus for processing the circuit board includes a physical metal surface treatment selected from a group consisting of evaporation plating, ion implantation, plasma processing and polishing.

The present invention also provides a resist whose ingredients are light-curing materials including acrylic acid, oligomer, monomer, adhesion agent, photoinitiator and filler.

In one embodiment of the present invention, the resist is in liquid form when it is spray-printed. Moreover, a spray-printable resist having an operating temperature range between −20˜200° C. and jettable fluid viscosity range between 0˜100 cps at jetting temperature can be used.

The present invention also provides a resist whose ingredients are thermal-curing materials including solvent, monomer, adhesion agent and filler.

In one embodiment of the present invention, the resist is in liquid form when it is spray-printed. Moreover, a spray-printable resist having an operating temperature range between −20˜200° C. and jettable fluid viscosity range between 0˜100 cps at jetting temperature can be used.

The resist in the present invention is only printed on a portion of the elective metal surface treatment areas rather than coating on the entire surface as in the conventional technique so that unnecessary material waste is prevented. In addition, the selective metal surface treatment process in the present invention uses a printing process to print a layer of resist on a portion of the selective metal surface treatment areas. Thus, compared with the conventional technique of having to go through dry film lamination, exposure and development processes, the processing time of the selective metal surface treatment process in the present embodiment is shorter.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1E are diagrams showing the steps for performing a selective Electroless Nickel Immersion Gold (ENIG) plating process of a conventional printed circuit board.

FIGS. 2A through 2D are diagrams showing the steps in a selective metal surface treatment process of a circuit board and its apparatus according to one embodiment of the present invention.

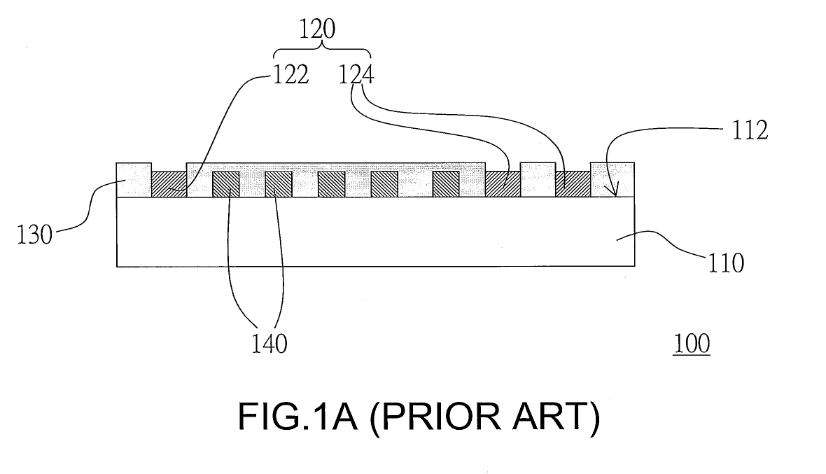

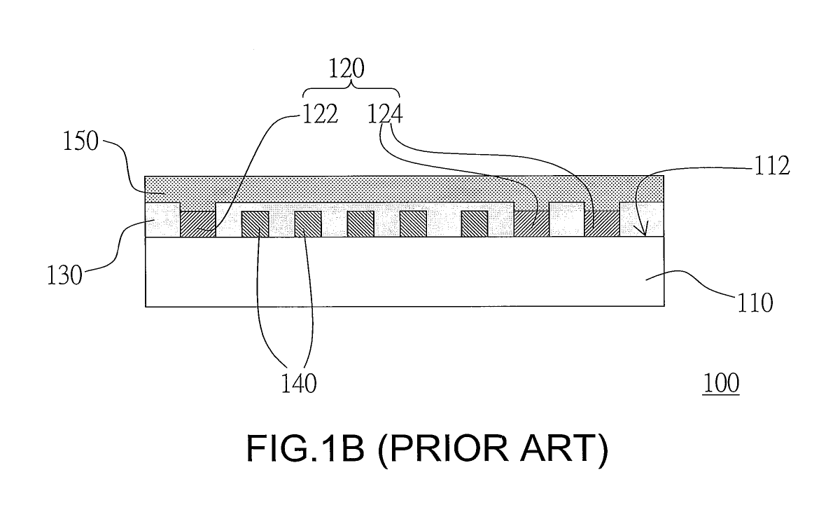

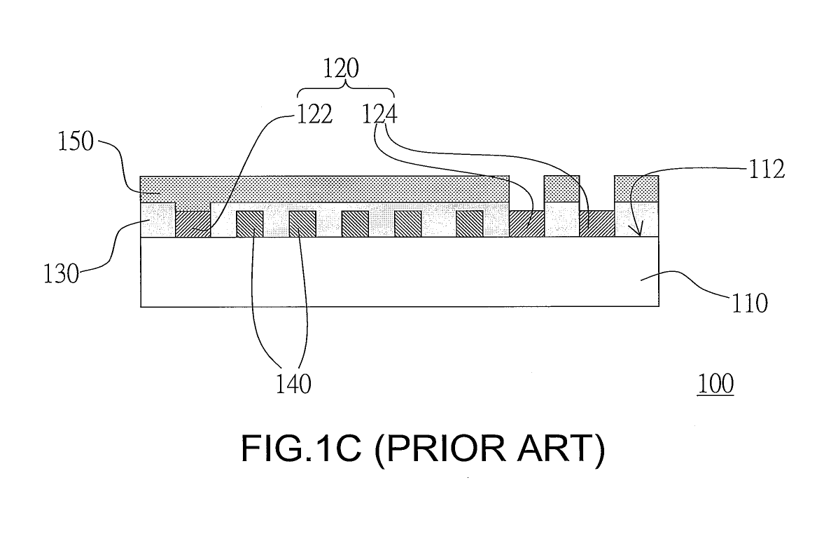

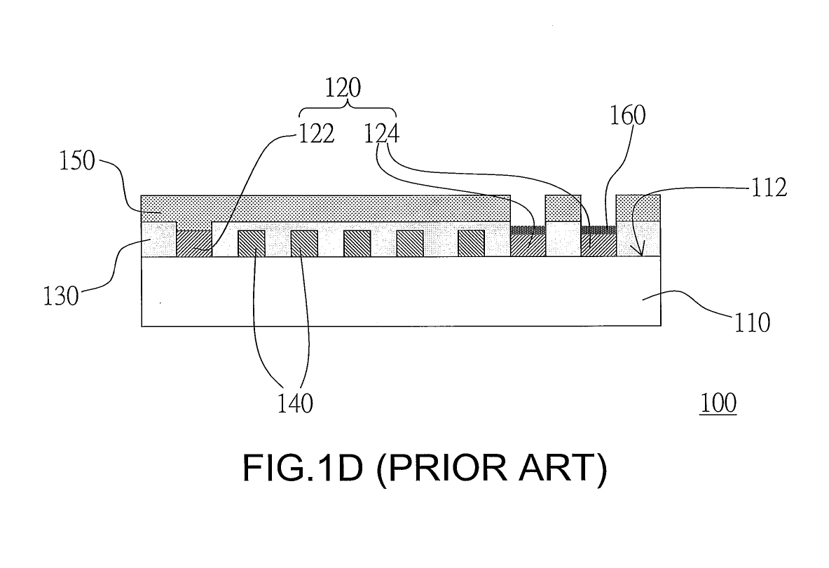

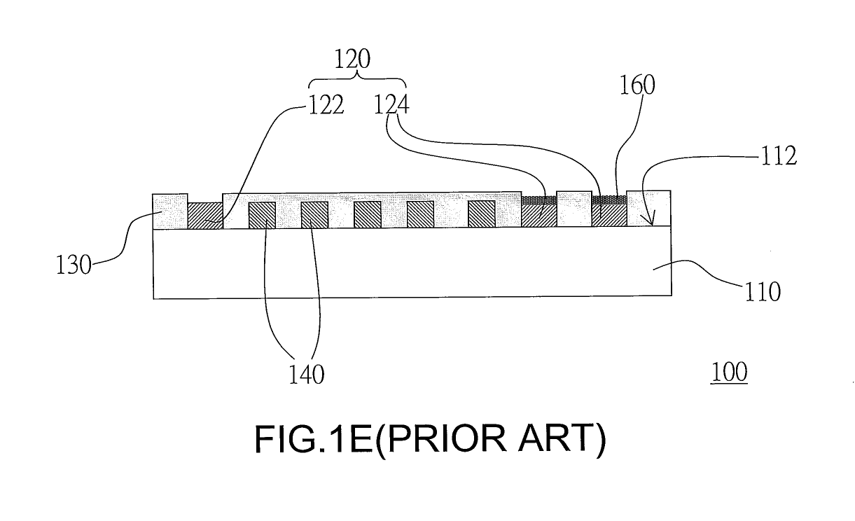

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

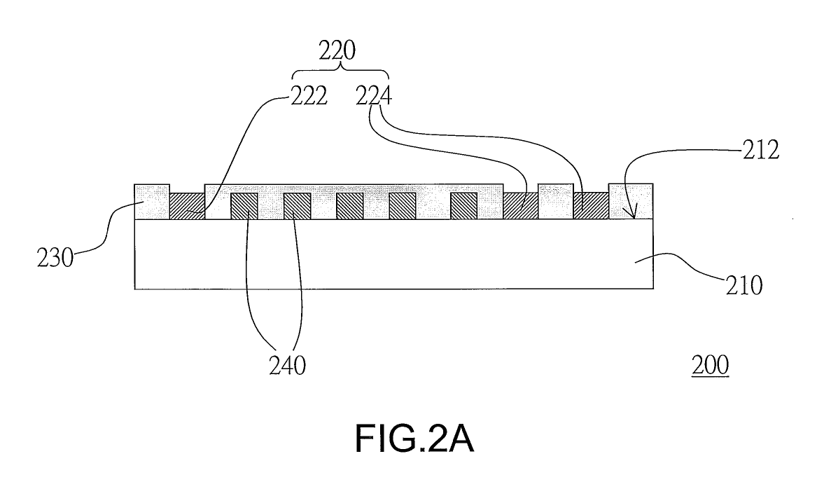

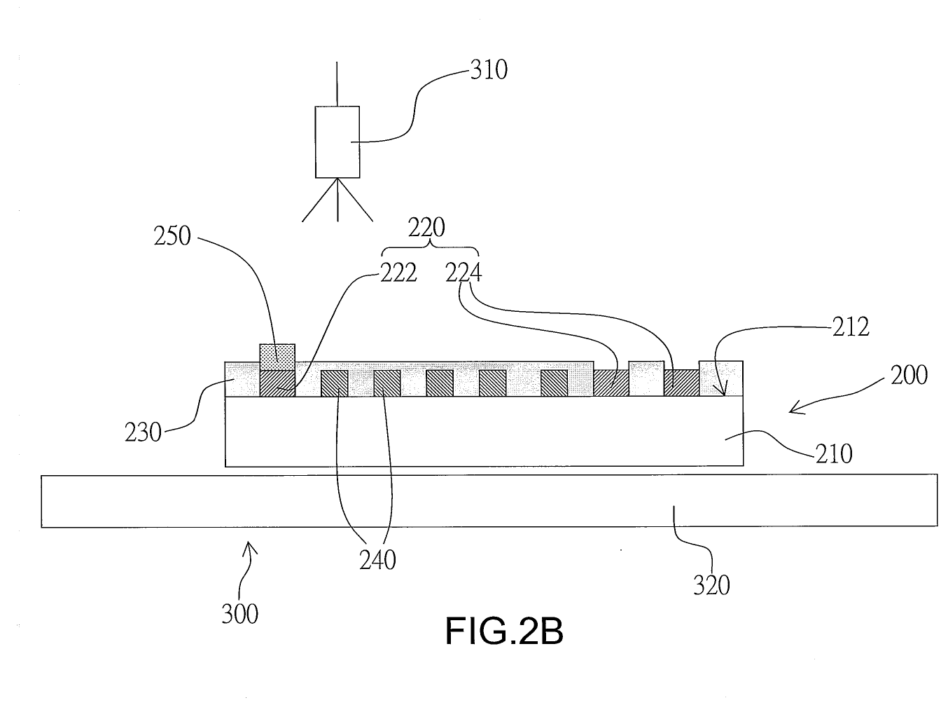

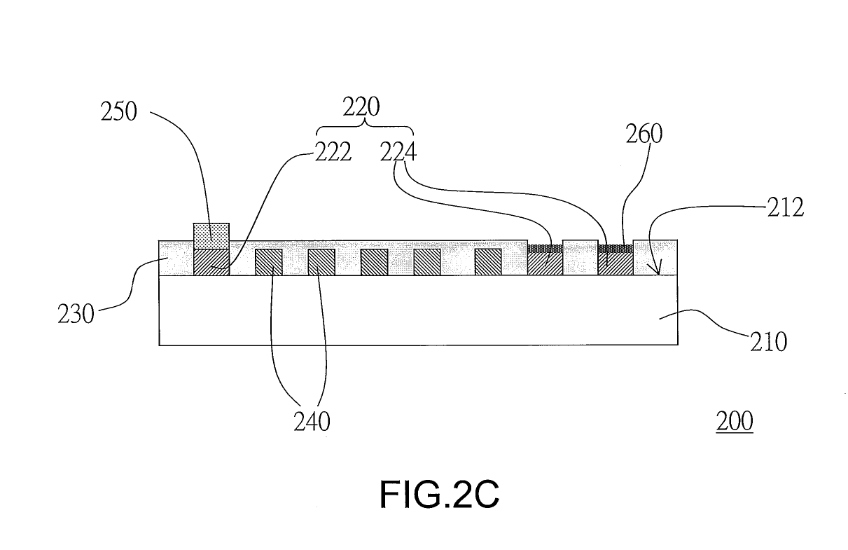

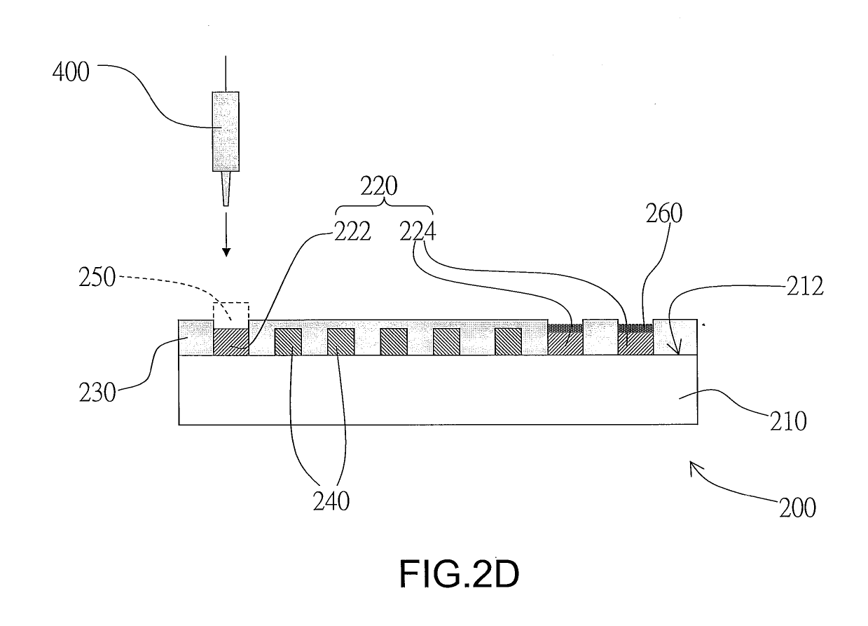

FIGS. 2A through 2D are diagrams showing the steps in a selective metal surface treatment process of a circuit board and its apparatus according to one embodiment of the present invention. As shown in FIG. 2A, the selective metal surface treatment process of a circuit board includes first providing a circuit board 200. The circuit board 200 has a substrate 210, a solder mask 230, a plurality of selective metal surface treatment areas 220 and a surface circuit 240. The substrate 210 may include a thin film, a multi-layered circuit board and/or a metal board, which serves as a carrier for the circuit board 200 and supports the surface circuit 240 and the selective metal surface treatment areas 220. In other words, the surface circuit 240 and the selective metal surface treatment areas 220 are located on the surface 212 of the substrate 210. The selective metal surface treatment areas 220 are, for example, wire-bonding pads, flip-chip bonding contacts or electrode contacts of passive devices. The solder mask 230 covers the surface 212 of the substrate 210 and the surface circuit 240 but exposes a plurality of selective metal surface treatment areas 220. The selective metal surface treatment areas 220 include first selective metal surface treatment areas 222 and second selective metal surface treatment areas 224. The first-selective metal surface treatment areas 222 and the second selective metal surface treatment areas 224 can be used to connect with different devices. For example, the first selective metal surface treatment areas 222 can be used to connect with passive devices and the second selective metal surface treatment areas 224 can be used to connected with a chip.

As shown in FIG. 2B, the circuit board 200 is placed on a printing platform 300. The printing platform 300 includes a carrier 320 and a printhead 310. The carrier 320 supports the circuit board 200 and the printhead 310 is disposed over the circuit board 200 for spray-printing resist 250 on the circuit board 200. The carrier 320 and the printhead 310 can be individually moved or moved relative to each other (here, the motion includes horizontal motion or vertical motion). Furthermore, the position between the two can be accurately determined. Thus, through the printing platform 300, the printhead 310 or the carrier 320 can be selectively moved to arrive at a desired print location. Afterwards, the printhead 310 selectively prints resist 250 on a selected metal surface treatment area 220 (for example, the first selective metal surface treatment area 222). The location of the resist after the printing process is shown in FIG. 2B. It should be noted that the resist 250 in the present embodiment is only printed on a portion of the selective metal surface treatment areas 220 (for example, the first selective metal surface treatment areas 222). Therefore, the actual quantity of resist used in the production process is lower so that the production cost is reduced. As a result, unnecessary material waste due to the need to coat a layer of resist on the entire surface in the conventional technique is prevented.

The resist 250 can be a light-curing material whose ingredients include acrylic acid, oligomer, monomer, adhesion agent, photoinitiator and filler or a thermal-curing material whose ingredients include solvent, monomer, adhesion agent and filler. However, the resist 250 is not limited to the foregoing materials. The commonly used material such as ink or anti soldering agent may also be used in the present invention. The resist 250 to be used in a spray-printing process is a liquid in a melted form. Moreover, a spray-printable resist having an operating temperature range between −20˜200° C. and a jettable fluid viscosity range between 0˜100 cps at jetting temperature can be used. Preferably, the operating temperature of the resist is between 10˜120° C. and the viscosity of the resist in the spray-printing operation is between 5˜20 cps.

Next, the circuit board 200 shown in FIG. 2B is placed inside a light-curing apparatus (not shown) or a thermal-curing apparatus (not shown) so that the light-curing apparatus can irradiate the resist 250 and cure it with light or the thermal-curing apparatus can heat up the resist 250 and cure it by heating. The light curing or thermal curing process is to set the resist 250 and increase the hardness of the resist 250 so that the first selective metal surface treatment areas 222 are protected in a subsequent process.

As shown in FIG. 2C, a surface treatment of the other selective metal surface treatment areas 220 (for example, the second selective metal surface treatment areas 224) without a printed resist 250 is performed. After the surface treatment, a covering layer 260 is formed on the surface of the second selective metal surface treatment areas 224. The step of performing a surface treatment of the other selective metal surface treatment areas 220 includes performing a chemical surface treatment selected from a group consisting of nickel-gold treatment, silver treatment, tin treatment, copper treatment and organic solderability preservative (OSP) treatment or performing a physical surface treatment selected from a group consisting of evaporation plating, ion implantation, plasma treatment and polishing. The purpose of performing a chemical surface treatment is to form an oxidation-resistant layer on the selective metal surface treatment areas 220 protecting the areas against any oxidation that might affect its conductive characteristics, and the physical surface treatment is performed according to different processing requirements. Yet, the selective metal surface treatment areas 220 (for example, the first selective metal treatment areas 222) protected on top by a printed resist 250 are unaffected by the surface treatment process.

As shown in FIG. 2D, a removing apparatus 400 is used to remove the printed resist 250 formed in the previous step. The method of removing the resist 250 includes, for example, spraying a chemical solvent through a nozzle to dissolve the resist 250, performing a plasma-etching process to etch the resist 250 or using any other methods familiar to anyone working in this field. Up to this point, the selective metal surface treatment process of the circuit board 200 is completed. It should be noted that a printing method is used to print the resist 250 in the present embodiment on a portion of the selective metal surface treatment areas 220. Therefore, the processing time in the present embodiment, compared with the conventional technique of performing thermal pressure process, exposure and development, is shorter. Moreover, the printhead has a fast moving speed and can be accurately positioned so that the printing process is particularly suitable for computerized operation and quality control.

In summary, the present invention has at least the following advantages and characteristics:

1. The resist in the present invention is only printed on a portion of the selective metal surface treatment areas, thereby avoiding the coating a layer of resist on an entire surface as in the conventional technique and leading to unnecessary material waste.

2. Because the resist is formed on a portion of the selective metal surface treatment areas by printing, the present invention has a shorter processing time compared with the conventional technique of forming a photoresist opening through a masking process.

3. Without using the conventional masking and photolithographic process to form the photoresist opening, less expensive equipment can be used. Moreover, the danger of contaminating the environment is lowered.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A selective metal surface treatment process of a circuit board, wherein the circuit board has a solder mask and a plurality of selective metal surface treatment areas, the solder mask covers the surface of the circuit board but exposes the selective metal surface treatment areas, comprising the steps of:
selectively printing a resist on a selective metal surface treatment area using a printhead;
performing a surface treatment on the other selective metal surface treatment areas; and
removing the printed resist.

2. The selective metal surface treatment process of claim 1, wherein after forming the resist on the selective metal surface treatment areas, further comprises irradiating the resist to cure the resist with light.

3. The selective metal surface treatment process of claim 1, wherein after forming the resist on the selective metal surface treatment areas, further comprises heating the resist to cure the resist by heat.

4. The selective metal surface treatment process of claim 1, wherein the resist is a liquid working under the printing condition, and the resist is a spray-printable material having an operating temperature range between −20˜200° C. and a jettable fluid viscosity range between 0˜100 cps at jetting temperature.

5. The selective metal surface treatment process of claim 1, wherein the step of performing a surface treatment on the other selective metal surface treatment areas comprises performing a chemical surface treatment selected from a group consisting of nickel-gold treatment, silver treatment, tin treatment, copper treatment and organic solderability preservative treatment.

6. The selective metal surface treatment process of claim 1, wherein the step of performing a surface treatment on the other selective metal surface treatment areas comprises performing a physical surface treatment selected from a group consisting of evaporation plating, ion implantation, plasma treatment and polishing.

7. A selective metal surface treatment apparatus of a circuit board, wherein the circuit board has a solder mask and a plurality of selective metal surface treatment areas, the solder mask covers the surface of the circuit board but exposes the selective metal surface treatment areas, comprising:
a printing platform for carrying the circuit board, wherein the printing platform includes a printhead for selectively printing a resist on a selective metal surface treatment area; and
a removing apparatus removing the printed resist after performing a surface treatment on the other selective metal surface treatment areas.

8. The selective metal surface treatment apparatus of claim 7, further comprises a light-curing apparatus for irradiating the resist to cure the resist with light.

9. The selective metal surface treatment apparatus of claim 7, further comprises a thermal-curing apparatus for heating the resist to cure the resist by heat.

10. The selective metal surface treatment apparatus of claim 7, wherein the resist is a liquid working under the printing condition, and the resist is a spray-printable material having an operating temperature range between −20˜200° C. and a jettable fluid viscosity range between 0˜100 cps at jetting temperature.

11. The selective metal surface treatment apparatus of claim 7, wherein the step of performing a surface treatment on the other selective metal surface treatment areas comprises performing a chemical surface treatment selected from a group consisting of nickel-gold treatment, silver treatment, tin treatment, copper treatment and organic solderability preservative treatment.

12. The selective metal surface treatment apparatus of claim 7, wherein the step of performing a surface treatment on the other selective metal surface treatment areas comprises performing a physical surface treatment selected from a group consisting of evaporation plating, ion implantation, plasma treatment and polishing.

13. A resist as in claim 1, comprising a light-curing material whose ingredients include acrylic acid, oligomer, monomer, adhesion agent, photoinitiator and filler.

14. The resist of claim 13, wherein the resist is a liquid working under a printing condition, and the resist is a spray-printable material having an operating temperature range between −20˜200° C. and a jettable fluid viscosity range between 0˜100 cps at jetting temperature.

15. A resist as in claim 7, comprising a light-curing material whose ingredients include acrylic acid, oligomer, monomer, adhesion agent, photoinitiator and filler.

16. The resist of claim 15, wherein the resist is a liquid working under a printing condition, and the resist is a spray-printable material having an operating temperature range between −20˜200° C. and a jettable fluid viscosity range between 0˜100 cps at jetting temperature.

17. A resist as in claim 1, comprising a thermal-curing material whose ingredients include including solvent, monomer, adhesion agent and filler.

18. The resist of claim 17, wherein the resist is a liquid working under a printing condition, and the resist is a spray-printable material having an operating temperature range between −20˜200° C. and a jettable fluid viscosity range between 0˜100 cps at jetting temperature.

19. A resist as in claim 7, comprising a thermal-curing material whose ingredients include including solvent, monomer, adhesion agent and filler.

20. The resist of claim 19, wherein the resist is a liquid working under a printing condition, and the resist is a spray-printable material having an operating temperature range between −20˜200° C. and a jettable fluid viscosity range between 0˜100 cps at jetting temperature.
